(19) United States
(12) Patent Application Publication
(10) Pub. No.: US 2026/0202381 A1
(43) Pub. Date: Jul. 16, 2026

(54) SENSOR ELEMENT, SENSOR ELEMENT MANUFACTURING METHOD, AND GAS MEASURING DEVICE

(71) Applicant: TDK CORPORATION, Tokyo (JP)

(72) Inventors: Mayumi TAKAHASHI, Tokyo (JP); Raitaro MASAOKA, Tokyo (JP)

(73) Assignee: TDK CORPORATION, Tokyo (JP)

(21) Appl. No.: 19/138,499

(22) PCT Filed: Dec. 27, 2023
(86) PCT No.: PCT/JP2023/046994

§ 371 Date: Jun. 12, 2025

Related U.S. Application Data
(60) Provisional application No. 63/435,648, filed on Dec. 28, 2022.

(51) Int. Cl. G01N 29/02; G01N 29/22; G01N 29/24; H10N 30/03; H10N 30/30

(52) U.S. Cl. CPC G01N 29/022; G01N 29/222; G01N 29/2443; H10N 30/03; H10N 30/302

(57) ABSTRACT

A sensor element includes a quartz crystal plate, an electrode made of a metallic film provided on the quartz crystal plate, and a sensitive film formed on the electrode. The sensitive film contains a tertiary amine, an acid, and a polymer.

Priority is claimed on U.S. Patent Provisional Application No. 63/435,648, filed Dec. 28, 2022, the content of which is incorporated herein by reference.

### TECHNICAL FIELD

The present invention relates to a sensor element, a sensor element manufacturing method, and a gas measuring device.

### BACKGROUND ART

In recent years, there has been an increasing demand for measuring gases in fields such as environmental measurement, the medical field, and the food industry. Gas measuring devices, for example, are used to measure toxic and/or flammable gases (vapors), water vapor in the air, and vapors of film formation materials in vacuum deposition processes. In recent years, gas measuring devices have come to be expected to be used in various fields such as detecting volatile organic gases serving as the cause of sick house syndrome, diagnosing diseases through exhaled breath, and applying to electronic noses (e-noses).

In conventional gas measuring devices, gas detection methods of a resistance type, a capacitance type, an optical type, a mass type, and the like are used. Gas measuring devices using mass-type gas detection methods include gas measuring devices having a sensor element with a quartz crystal resonator and a sensitive film configured to adsorb the detection target gas and using a quartz crystal microbalance (QCM) method for measuring the mass of molecules using the oscillation of the quartz crystal resonator. Sensor elements using the QCM method are highly sensitive and can be easily miniaturized and easily manufactured by forming a sensitive film on a quartz crystal resonator.

Patent Document 1 describes an odor sensor including two or more sensor elements that have a substance adsorption film that adsorbs odor substances and an electric signal conversion unit configured to measure electrical characteristics of the substance adsorption film, and an odor measurement system using the odor sensor. Moreover, as described in Patent Document 1, the substance adsorption film of the sensor element includes a basic skeleton including a conductive polymer and a dopant configured to change substance characteristics of the basic skeleton of the conductive polymer. Furthermore, as described in Patent Document 1, the substance adsorption films of the two or more sensor elements each have a different content ratio between the dopant and the conductive polymer.

### CITATION LIST

### Patent Document

Patent Document 1: Japanese Unexamined Patent Application, First Publication No. 2019-124700

### SUMMARY OF INVENTION

### Technical Problem

In recent years, there has been a demand for high-sensitivity detection of aldehyde gas such as formaldehyde gas. In particular, there is an increasing demand for high-sensitivity detection of formaldehyde gas, which is one of volatile organic gases serving as the cause of sick house syndrome.

The present invention has been made in consideration of the above circumstances and an objective of the present invention is to provide a sensor element that can detect aldehyde gas with high sensitivity using a quartz crystal microbalance (QCM) method.

Moreover, an objective of the present invention is to provide a gas measuring device including the sensor element of the present invention.

### Solution to Problem

[1] A sensor element including:
a quartz crystal plate;
an electrode made of a metallic film provided on the quartz crystal plate; and
a sensitive film formed on the electrode,
wherein the sensitive film contains a tertiary amine, an acid, and a polymer.

[2] The sensor element according to [1], wherein the tertiary amine is one or more of amines selected from aliphatic amines, aromatic amines, and heterocyclic amines, and is solid in a range of 0° C. to 100° C.

[3] The sensor element according to [1], wherein the acid is one or more of acids selected from inorganic acids, sulfonic acids, and carboxylic acids.

[4] The sensor element according to [1], wherein the polymer is one or more of polymers selected from polystyrene, polymethyl methacrylate, and polyimide.

[5] The sensor element according to [1], wherein the tertiary amine is a crystal having an average particle size in a range of 0.05 μm to 2 μm.

[6] A gas measuring device comprising the sensor element according to any one of[1] to [5].

[7] A method for manufacturing the sensor element having the sensitive film containing the tertiary amine, the acid, and the polymer according to any one of [1] to [5], the method including:
a step of forming the sensitive film;
a first solution preparation step of preparing a first solution containing the tertiary amine and the acid;
a second solution preparation step of dissolving the polymer in a dispersion solvent to prepare a second solution;
a raw material solution preparation step of mixing the first solution and the second solution to prepare a raw material solution; and
a film formation step of applying and drying the raw material solution.

### Advantageous Effects of Invention

The sensor element of the present invention has a sensitive film containing a tertiary amine, an acid, and a polymer. Therefore, when aldehyde gas comes into contact with the sensitive film of the sensor element, the aldehyde gas reacts with the tertiary amine due to a catalytic reaction of the acid, and a hemiaminal is produced. At the same time, a reaction in which the hemiaminal decomposes to release the aldehyde gas and return to the tertiary amine occurs. It is estimated that an amount of hemiaminal produced in this reversible reaction instantly changes with a concentration of aldehyde gas in contact with the sensitive film, thereby changing the mass of the sensitive film provided on the quartz crystal plate and changing a fundamental frequency of the quartz crystal resonator. Thereby, the sensor element of the present invention can continuously detect the aldehyde gas with high sensitivity using the quartz crystal microbalance (QCM) method.

Moreover, the gas measuring device of the present invention includes the sensor element of the present invention. Therefore, the gas measuring device of the present invention can continuously detect aldehyde gas with high sensitivity.

### BRIEF DESCRIPTION OF DRAWINGS

FIG. 1 is a plan view showing an example of a sensor element of the present embodiment.

FIG. 2 is a cross-sectional view of the sensor element of the present embodiment cut along line A-A′ shown in FIG. 1.

FIG. 3 is an explanatory process diagram of an example of a sensor element measuring method of the present embodiment.

FIG. 4 is a schematic diagram showing a gas measuring device of the present embodiment.

FIG. 5 is a graph showing a vibration frequency variation when formaldehyde gas is supplied to a flow cell in which a sensor element of Inventive Example 1 is installed.

FIG. 6 is a graph showing a vibration frequency variation when ethanol gas is supplied to a flow cell in which the sensor element of Inventive Example 1 is installed.

FIG. 7 is a graph showing a vibration frequency variation when formaldehyde gas is supplied to a flow cell in which a sensor element of Comparative Example 5 is installed.

FIG. 8 is a graph showing a vibration frequency variation when ethanol gas is supplied to a flow cell in which the sensor element of Comparative Example 5 is installed.

FIG. 9 is a micrograph of a sensitive film of the sensor element of Inventive Example 1.

FIG. 10 is a micrograph of a sensitive film of the sensor element of Comparative Example 1.

### DESCRIPTION OF EMBODIMENTS

To accomplish the above-mentioned objective, the inventors of the present invention have focused on a sensitive film of a sensor element to perform a detection process with high sensitivity using a quartz crystal microbalance (QCM) method and have conducted intensive research, as will be described below.

Conventionally, in gas measuring devices in which a sensor element having a quartz crystal resonator is provided, when a gas is adsorbed onto a sensitive film of the sensor element and a mass thereof increases, a fundamental frequency of the quartz crystal resonator changes to detect a gas concentration. Moreover, the sensitive film of the sensor element may be a polymer film to which a dopant such as an acid or alkali is added. For example, when the dopant is added to the polymer film and the sensitive film is formed with a charge bias, it is possible to promote the adsorption of a gas consisting of polar molecules such as aldehyde gas for the sensitive film, thereby increasing the sensitivity.

However, such a sensitive film adsorbs not only aldehyde gas but also other gases consisting of polar molecules and it is not possible to distinguish whether the sensitive film has adsorbed aldehyde gas, other gases other than the aldehyde gas, or both the aldehyde gas and the other gases other than the aldehyde gas. Therefore, it is difficult to selectively detect a concentration of aldehyde gas in a mixed gas containing, for example, aldehyde gas and alcohol gas such as ethanol using a sensor element having the sensitive film with high sensitivity.

Therefore, the inventors of the present invention have conceived of a method for selectively detecting aldehyde gas by utilizing a chemical reaction between an aldehyde and a compound highly reactive with the aldehyde without being reactive with alcohols. This chemical reaction is a reaction between an aldehyde and a tertiary amine to produce a hemiaminal.

However, as a result of the examination by the inventors of the present invention, the aldehyde gas could not be detected by a sensor element having a sensitive film made of a tertiary amine. This is considered to be because the tertiary amine in the sensitive film does not react with the aldehyde gas. Therefore, the inventors of the present invention manufactured a sensor element having a sensitive film made of a tertiary amine and an acid to improve a reaction rate between the tertiary amine in the sensitive film and the aldehyde. However, this sensor element was also unable to detect the aldehyde gas.

Therefore, the inventors of the present invention have focused on a crystal size of the tertiary amine to promote the reaction between the tertiary amine in the sensitive film and the aldehyde and have further examined it. As a result, it was found that it is only necessary to form the sensitive film by a method for mixing, applying, and drying a first solution containing a tertiary amine and an acid and a second solution in which a polymer is dissolved in a dispersion solvent.

For the sensitive film formed by the above-described method, because the crystal growth of the tertiary amine during a film formation process is suppressed, the tertiary amine of the sensitive film has a fine crystal. As a result, it is estimated that a contact area between the tertiary amine and the aldehyde gas is sufficiently large and the tertiary amine in the sensitive film is more likely to react with the aldehyde.

Furthermore, the inventors of the present invention have confirmed that the aldehyde gas can be detected with high sensitivity by using a sensor element having the above-described sensitive film and that the aldehyde gas can be selectively detected even if it is contained in a mixed gas containing gases other than the aldehyde gas, and have conceived the present invention.

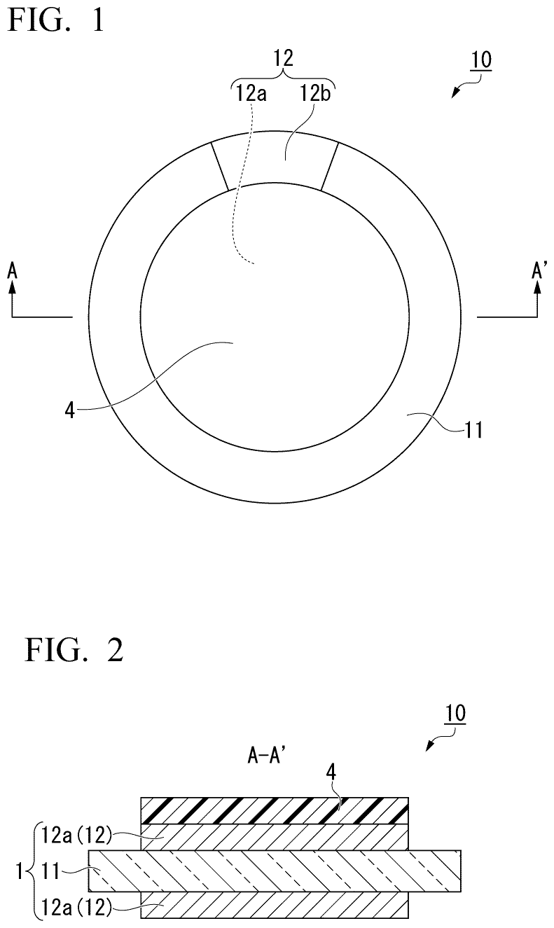

The sensor element, the sensor element manufacturing method, and the gas measuring device of the present invention will be described in detail below with reference to the drawings.

[Sensor element] FIG. 1 is a plan view showing an example of the sensor element of the present embodiment. FIG. 2 is a cross-sectional view of the sensor element of the present embodiment cut along line A-A′ shown in FIG. 1.

The sensor element 10 of the present embodiment shown in FIG. 1 quantifies a concentration of a detection target gas using a quartz crystal microbalance (QCM) method. As shown in FIG. 1, the sensor element 10 of the present embodiment is approximately circular when seen from above. As shown in FIG. 2, the sensor element 10 is a quartz crystal resonator 1 with a sensitive film 4 laminated on one of electrodes 12 provided on both sides of the quartz crystal resonator 1. The sensor element 10 is connected to a frequency measuring device that measures a vibration frequency (a frequency) at which the quartz crystal resonator 1 oscillates and detects a variation in the frequency using two lead wires (not shown) electrically connected to the two electrodes 12, respectively. Known lead wires and frequency measuring devices can be used.

### (Quartz Crystal Resonator)

The quartz crystal resonator 1 has a quartz crystal plate 11 and electrodes 12 provided on both sides of the quartz crystal plate 11, as shown in FIG. 2. A fundamental frequency of the quartz crystal resonator 1 changes in proportion to a change in the mass of the sensitive film 4 placed on one electrode 12. That is, when the mass of the sensitive film 4 changes as the aldehyde gas, which is the detection target that comes into contact with the sensitive film 4, reacts with the tertiary amine contained in the sensitive film 4 in the presence of an acid, the fundamental frequency of the quartz crystal resonator 1 changes.

A known quartz crystal plate 11 can be used. In the sensor element 10 of the present embodiment, the quartz crystal plate 11 that is approximately circular when seen from above is used. A diameter of the quartz crystal plate 11 can be, for example, between 0.1 mm and 25 mm, preferably between 0.5 mm and 10 mm. A thickness of the quartz crystal plate 11 can be, for example, between 50 μm and 500 μm, preferably between 100 μm to 300 μm. A fundamental frequency when an electric field is applied to the electrode 12 of the quartz crystal resonator 1 is decided by the thickness of the quartz crystal plate 11. The thinner the quartz crystal plate 11, the higher the sensitivity. On the other hand, the thicker the quartz crystal plate 11, the wider a concentration range of the aldehyde gas that can be detected. Therefore, the thickness of the quartz crystal plate 11 can be appropriately decided in accordance with an application of the sensor element 10 such as a concentration of the aldehyde detection target gas.

In the sensor element 10 of the present embodiment, the case where the quartz crystal plate 11 is approximately circular when seen from above has been described as an example. However, a shape of the quartz crystal plate 11 is not limited to the approximately circular shape when seen from above and can be appropriately decided in accordance with the application of the sensor element 10.

The electrodes 12 are made of metallic films provided on both sides of the quartz crystal plate 11. When seen from above, each electrode 12 has a circular central region 12a centered at the same center as the quartz crystal plate 11 and a connection region 12b extending from the edge of the central region 12a to the edge of the quartz crystal plate 11.

The central region 12a of one electrode 12 is used as a sensitive film formation surface on the quartz crystal resonator 1 on which the sensitive film 4 is formed. As shown in FIGS. 1 and 2, the central region 12a of one electrode 12 is covered by the sensitive film 4 having approximately the same shape as the central region 12a when seen from above.

Moreover, the connection region 12b of the electrode 12 is exposed on the surface of the sensor element 10, as shown in FIG. 1. The connection region 12b is a region for connecting a lead wire (not shown) that electrically connects the sensor element 10 and a frequency measuring device. The connection regions 12b of the two electrodes 12 may be arranged at a position where they overlap when seen from above or may be arranged at a position where they do not overlap when seen from above.

The electrode 12 is made of a metallic film. Examples of materials that can be used for the metallic film include gold, silver, copper, platinum, and the like. Preferably, the electrode 12 has positive electric charges. The electrode 12 can be formed by a known method.

In the sensor element 10 of the present embodiment, the electrode 12 has the circular central region 12a and the connection region 12b extending from an edge of the central region 12a to an edge of the quartz crystal plate 11, but a planar shape and thickness of the electrode 12 are not particularly limited.

### (Sensitive Film)

The sensitive film 4 is formed on the sensitive film formation surface of the quartz crystal resonator 1. The shape of the sensitive film 4 is not particularly limited.

The thickness of the sensitive film 4 can be, for example, between 0.1 μm and 100 μm, preferably between 1 μm and 50 μm, and can be appropriately decided in accordance with the type and concentration of the aldehyde gas that is a detection target and the like. If the thickness of the sensitive film 4 is 0.1 μm or more, it is preferable because the aldehyde gas becomes more likely to react with the tertiary amine, and the aldehyde gas can be detected with higher sensitivity. If the thickness of the sensitive film 4 is 100 μm or less, it is preferable because the sensitive film 4 can be easily manufactured by the manufacturing method to be described below.

The sensitive film 4 contains a tertiary amine, an acid, and a polymer. If the sensitive film 4 comes into contact with the aldehyde gas, its mass immediately changes with the concentration of the aldehyde gas. This is because the aldehyde gas reacts with the tertiary amine due to a catalytic reaction of the acid to produce a hemiaminal, the produced hemiaminal decomposes to release the aldehyde gas, and a reversible reaction occurs with the reaction that returns to the tertiary amine.

In addition, alcohol gas made of ethanol or the like and ketone gas do not react with the tertiary amine even under the presence of an acid. Therefore, when a mixed gas consisting of aldehyde gas and alcohol gas and/or ketone gas comes into contact with the sensitive film 4, the reversible reaction occurs selectively only with the aldehyde gas in the mixed gas, and the alcohol gas and/or the ketone gas do not affect an amount of hemiaminal produced by the above-described reversible reaction. Therefore, the sensor element 10 of the present embodiment can selectively detect the aldehyde gas with high sensitivity even if the aldehyde gas is contained in a mixed gas containing alcohol gas and/or ketone gas.

The tertiary amine contained in the sensitive film 4 is preferably one or two or more of amines selected from aliphatic amines, aromatic amines, and heterocyclic amines. Specifically, examples of the tertiary amine include triethylenediamine (diazabicyclooctane (DABCO)), N,N-dimethyloctadecylamine, N,N-dimethylbehenylamine, and the like. It is preferable to use triethylenediamine among these tertiary amines because the triethylenediamine has high reactivity with aldehyde gas and enables aldehyde gas to be detected with high sensitivity in the sensitive film 4.

Moreover, the tertiary amine contained in the sensitive film 4 is preferably solid in a range of 0° C. to 100° C., more preferably solid in a range of 20° C. to 80° C., and even more preferably solid in a range of 25° C. to 80° C. When the aldehyde gas comes into contact with the sensitive film 4, if the tertiary amine contained in the sensitive film 4 is solid, the occurrence of the above-mentioned reversible reaction is more stable than when the tertiary amine is liquid, and the aldehyde gas can be detected with higher sensitivity.

The tertiary amine contained in the sensitive film 4 is preferably one or more of amines selected from aliphatic amines, aromatic amines, and heterocyclic amines, and is more preferably solid in a range of 0° C. to 100° C. under normal pressure (0.1 MPa).

The tertiary amine contained in the sensitive film 4 is preferably a crystal with an average particle size in a range of 0.05 μm to 2 μm and is more preferably a crystal with an average particle size in a range of 0.1 μm to 1 μm. When the tertiary amine is a crystal with an average particle size of 0.05 μm or more, it is preferable because it can be easily produced by the production method to be described below. Moreover, when the tertiary amine is a crystal having an average particle size of 2 μm or less, because a contact area between the tertiary amine and the aldehyde gas is large, the tertiary amine in the sensitive film is more likely to react with the aldehyde preferably.

The acid contained in the sensitive film 4 is preferably one or more of acids selected from inorganic acids, sulfonic acids, and carboxylic acids. Specifically, examples of the acid include dodecylbenzenesulfonic acid, p-toluenesulfonic acid, 1-octanesulfonic acid, n-octanoic acid, stearic acid, acetic acid, hydrochloric acid, sulfuric acid, phosphoric acid, and the like. Among these acids, it is preferable to use the sulfonic acid, particularly, dodecylbenzenesulfonic acid, because the reversible reaction occurs stably.

As the polymer contained in the sensitive film 4, for example, polystyrene, polymethyl methacrylate (PMMA), polymethacrylic acid ester, polyacrylamide, polyimide, polyethylene, polylactic acid, and the like can be used. The polymer contained in the sensitive film 4 may be one or more. The polymer contained in the sensitive film 4 is preferably polystyrene. In this case, the manufacturing method to be described below makes it easy to form the sensitive film 4 in which fine tertiary amine particles are uniformly distributed and in which the aldehyde gas and the tertiary amine easily come into contact with each other. This is estimated because polystyrene has high hydrophobicity and therefore the polystyrene and the tertiary amine do not mix well with each other and the crystal growth of the tertiary amine is suppressed when a raw material solution containing polystyrene and a hydrophilic tertiary amine is applied and dried to form the sensitive film 4.

The content of the tertiary amine contained in the sensitive film 4 is preferably 5 to 15 parts by mass, more preferably 7 to 10 parts by mass, with respect to 100 parts by mass of the polymer contained in the sensitive film 4. If the content of the tertiary amine is 5 parts by mass or more, the sensitive film 4 in which the above-described reversible reaction occurs stably is formed. Moreover, if the content of the tertiary amine is 15 parts by mass or less, it is preferable because particles with high crystallinity made of the tertiary amine are easily produced in the sensitive film 4.

The content of the acid contained in the sensitive film 4 is preferably 1.0 to 2.5 parts by mass, more preferably 0.8 to 1.5 parts by mass, and even more preferably 1.2 to 1.5 parts by mass, with respect to 100 parts by mass of the polymer contained in the sensitive film 4. If the content of the acid is 1.0 part by mass or more, the catalytic reaction that promotes the reaction between the aldehyde gas and the tertiary amine becomes better, and the sensitive film 4 in which the occurrence of the reversible reaction is stable is formed. Moreover, if the content of the acid is 2.5 parts by mass or less, the surface of the particles made of the tertiary amine is not covered with the acid and the sensitive film 4 preferably has a larger contact area between the particles made of the tertiary amine and the aldehyde gas.

### “Method for Manufacturing Sensor Element”

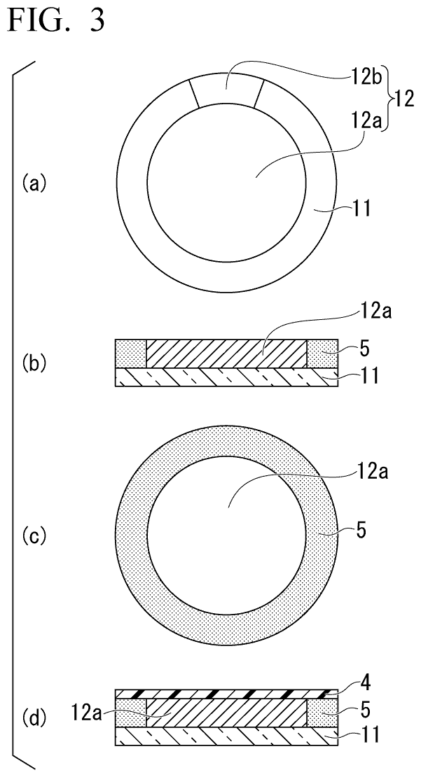

Next, an example of a method for manufacturing a sensor element of the present embodiment will be described. FIG. 3 is an explanatory process diagram of an example of the method for manufacturing the sensor element of the present embodiment. FIGS. 3(a) and 3(c) are plan views of the sensor element during manufacturing. FIGS. 3(b) and 3(d) are cross-sectional views of the sensor element during manufacturing corresponding to the position cut along line A-A′ shown in FIG. 1.

In the method for manufacturing the sensor element 10 of the present embodiment, first, as shown in FIG. 3(a), a quartz crystal resonator 1 having a quartz crystal plate 11 and electrodes 12 provided on both sides of the quartz crystal plate 11 is provided. Subsequently, both sides of the quartz crystal resonator 1 are cleaned using known methods such as ultrasonic cleaning, ultraviolet light irradiation, ozone treatment, and plasma treatment.

Subsequently, a protective mask is formed on a surface of the quartz crystal resonator 1. As shown in FIGS. 3(b) and 3(c), the protective mask 5 is formed on one side of the quartz crystal resonator 1 to cover the surface of the quartz crystal resonator 1 in a state in which only the central region 12a (a sensitive film formation surface) of the electrode 12 is exposed. The protective mask 5 is also formed on the entire other side of the quartz crystal resonator 1 (the electrode and the protective mask 5 on the other side are not shown). As the protective mask 5, for example, a known one such as a light-curing resin film such as an ultraviolet curable resin film, a thermosetting resin film, a thermally peelable resin sheet, and a masking tape can be used.

### (Sensitive Film Forming Process)

Next, as shown in FIG. 3(d), the sensitive film 4 containing a tertiary amine, an acid, and a polymer is formed on the central region 12a (the sensitive film formation surface) of the electrode 12 of the quartz crystal resonator 1 on which the protective mask 5 is formed, by a method to be described below.

First, a tertiary amine is dissolved in water to prepare a tertiary amine solution. Subsequently, an acid is dropped into the tertiary amine solution to prepare a first solution (a first solution preparation process). A concentration of the tertiary amine solution in the first solution can be, for example, 5.0% to 1.5% by mass. A concentration of the acid in the first solution can be, for example, 0.7% to 2.2% by mass.

Subsequently, the polymer is dissolved in a dispersion solvent to prepare a second solution (a second solution preparation process).

The dispersion solvent can be, for example, acetone, methyl ethyl ketone, tetrahydrofuran, dimethylformamide, or the like, and is appropriately decided in accordance with a type of polymer. A concentration of the polymer in the second solution can be, for example, 10% to 20% by mass.

Subsequently, the first solution and the second solution are mixed and stirred to prepare a raw material solution in which the first solution and the second solution are dispersed (a raw material solution preparation process). A ratio of the tertiary amine, acid, and polymer in the raw material solution is adjusted to be the same as a ratio of the tertiary amine, acid, and polymer in the sensitive film 4. A known method can be used to stir the raw material solution.

Subsequently, the raw material solution is applied to the central region 12a (the sensitive film formation surface) of the electrode 12 in the quartz crystal resonator 1 using a known method such as a drop cast method, a spin coat method, or an inkjet method.

Subsequently, the quartz crystal resonator 1 to which the raw material solution has been applied is dried for 15 to 30 minutes at 60° C. to 80° C. in a nitrogen atmosphere (a film formation process).

By carrying out the above steps, the sensitive film 4 attached to the sensitive film formation surface on the quartz crystal resonator 1 is obtained as shown in FIG. 3(d).

Subsequently, the protective mask 5 is removed from the quartz crystal resonator 1 on which the sensitive film 4 has been formed. The protective mask 5 can be removed by a known method in accordance with a material of the protective mask 5 in use. For example, when a thermally peelable resin sheet is used as the protective mask 5, the protective mask 5 can be removed by heating it at a predetermined temperature for a predetermined time. Also, for example, when the protective mask 5 made of a thermosetting resin or photocurable resin is used, the protective mask 5 can be removed by dissolving it in an organic solvent or the like.

According to the above steps, the sensor element 10 of the present embodiment is obtained.

The sensor element 10 of the present embodiment can be preferably used when aldehyde gas is detected, particularly when the aldehyde gas in a mixed gas containing the aldehyde gas and other gases is detected. Examples of the aldehyde gas include formaldehyde, acetaldehyde, and the like. When the aldehyde gas is formaldehyde gas, which is one of the volatile organic gases serving as the cause of sick house syndrome, because the demand for selective detection with high sensitivity is increasing, this is useful.

### “Gas Measuring Device”

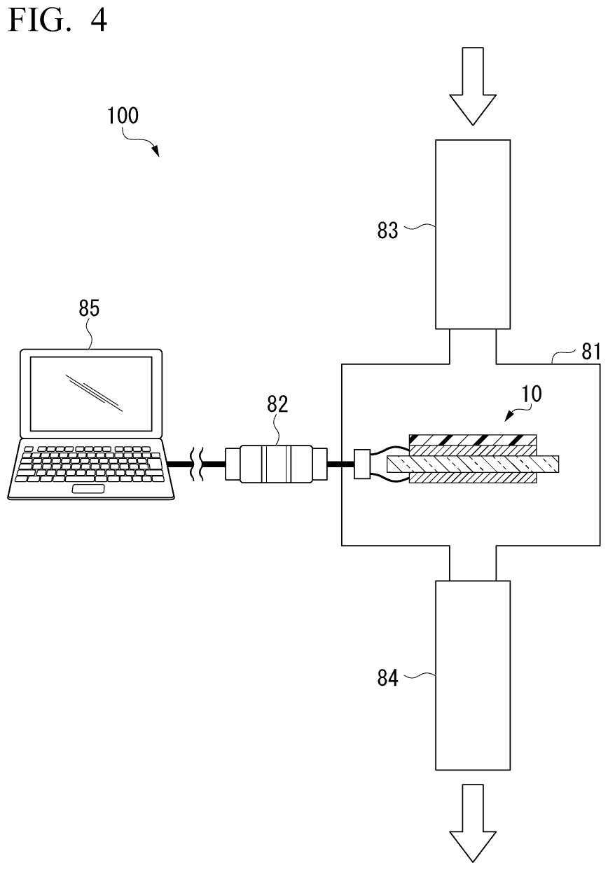

Next, the gas measuring device of the present embodiment will be described as an example. FIG. 4 is a schematic diagram showing the gas measuring device of the present embodiment. The gas measuring device 100 of the present embodiment includes the sensor element 10 of the present embodiment, a flow cell 81, a gas supply means 83, a gas exhaust means 84, a frequency measuring device 82, and a personal computer 85.

The flow cell 81 houses the sensor element 10. In the gas measuring device 100 of the present embodiment, the sensor element 10 comes into contact with aldehyde gas (or a mixed gas containing the aldehyde gas and other gases) to be detected in the flow cell 81, and a concentration of the aldehyde gas is measured.

The gas supply means 83 supplies aldehyde gas (or a mixed gas containing the aldehyde gas and other gases) that is a detection target and a base gas at a predetermined mixing ratio and flow rate to the flow cell 81.

The gas exhaust means 84 exhausts the aldehyde gas (or a mixed gas containing the aldehyde gas and other gases) that is a detection target and the base gas from the flow cell 81.

The frequency measuring device 82 measures a vibration frequency (a frequency) at which the quartz crystal resonator 1 oscillates and detects a frequency variation. The frequency measuring device 82 is electrically connected to the connection regions 12b of the two electrodes 12 of the sensor element 10 by lead wires.

The personal computer 85 is communicatively connected to the frequency measuring device 82 by wire or wirelessly and outputs a detection result of the frequency measuring device 82.

In the gas measuring device 100 of the present embodiment, known members other than the sensor element 10 can be used.

The gas measuring device 100 of the present embodiment includes the sensor element 10 of the present embodiment. The sensor element 10 of the present embodiment has a sensitive film 4 containing a tertiary amine, an acid, and a polymer. Therefore, when aldehyde gas comes into contact with the sensitive film 4 of the sensor element 10, the aldehyde gas reacts with the tertiary amine due to the catalytic reaction of the acid, and a hemiaminal is produced. At the same time, a reaction in which the hemiaminal decomposes to release aldehyde gas and return to a tertiary amine occurs. It is estimated that the amount of hemiaminal produced in this reversible reaction instantly changes with the concentration of aldehyde gas in contact with the sensitive film, thereby changing the mass of the sensitive film provided on the quartz crystal plate and changing the fundamental frequency of the quartz crystal resonator. Thereby, the sensor element 10 of the present embodiment can continuously detect aldehyde gas with high sensitivity using the quartz crystal microbalance (QCM) method.

Moreover, tertiary amines do not react with alcohols and/or ketones. Therefore, the sensor element 10 of the present embodiment can selectively detect aldehyde gas with high sensitivity even if the aldehyde gas is contained in a mixed gas containing, for example, alcohol gas and/or ketone gas.

Moreover, in the sensor element 10 of the present embodiment, after the aldehyde gas, which is supplied to the flow cell 81 by the gas supply means 83 and comes into contact with the sensitive film 4, reacts with the tertiary amine to become a hemiaminal and is incorporated into the sensitive film 4, it is released as aldehyde gas from the sensitive membrane 4 by decomposition of the hemiaminal and is discharged from the flow cell 81 by the gas exhaust means 84. Therefore, even if aldehyde gas (or a mixed gas containing the aldehyde gas and other gases) is continuously supplied to the flow cell 81 and the aldehyde gas is continuously brought into contact with the sensitive film 4 of the sensor element 10, the aldehyde gas and the hemiaminal, which is a reaction product of the aldehyde gas and the tertiary amine, do not accumulate on the sensitive film 4. Therefore, even if aldehyde gas (or a mixed gas containing the aldehyde gas and other gases) is continuously brought into contact with the sensitive film 4, the sensitivity of the sensor element 10 does not decrease, and aldehyde gas can be continuously detected with high sensitivity.

On the other hand, when the sensor element, for example, detects a change in the fundamental frequency of the quartz crystal resonator due to an increase in the mass of the sensitive film by adsorbing a detection target gas onto the sensitive film, if the detection target gas is continuously brought into contact with the sensitive film, the detection target gas adsorbed onto the sensitive film accumulates, such that the surface of the sensitive film is gradually covered therewith, it is difficult for the detection target gas to be adsorbed onto the sensitive film, and the sensitivity decreases.

Moreover, when the sensor element, for example, detects a change in the fundamental frequency of the quartz crystal resonator due to an increase in the mass of the sensitive film by adsorbing the detection target gas onto the sensitive film, it is difficult to adsorb only the aldehyde gas in a mixed gas containing the aldehyde gas and other gases onto the sensitive film. Therefore, it is difficult for this sensor element to selectively detect aldehyde gas in a mixed gas, and it is also difficult to detect aldehyde when the mixed gas contains only a small amount of aldehyde.

Moreover, because the gas measuring device 100 of the present embodiment includes the sensor element 10 of the present embodiment, it is possible to continuously detect aldehyde gas with high sensitivity. Moreover, according to the gas measuring device 100 of the present embodiment, even if aldehyde gas, for example, is contained in a mixed gas containing alcohol gas and/or ketone gas, the aldehyde gas in the mixed gas can be selectively detected continuously with high sensitivity.

Although the gas measuring device 100 including one sensor element 10 has been described as an example in the present embodiment, the number of sensor elements provided in the gas measuring device may be two or more.

While the embodiments of the present invention have been described in detail above, the constituent elements and their combinations in the respective embodiments are merely examples, and additions, omissions, substitutions, and other modifications to the constituent elements are possible without departing from the scope and spirit of the present invention.

### EXAMPLES

### [First Inventive Example] “Manufacturing of Sensor Element”

First, as shown in FIG. 3(a), a quartz crystal resonator 1 (product name: SEN-9E-H-10, with a fundamental frequency of 9 MHz, manufactured by TAMADEVICE Co., Ltd.) was provided. The quartz crystal resonator 1 has a quartz crystal plate 11, which is circular when seen from above and has a diameter of 8.7 mm, and electrodes 12, which are provided on both sides of the quartz crystal plate 11 and have a central region 12a made of a gold film with a diameter of 5.0 mm,

Subsequently, the quartz crystal resonator 1 was immersed in acetone and ultrasonically cleaned for 15 minutes, immersed in pure water, ultrasonically cleaned for 15 minutes, and then dried in air at a temperature of 70° C., thereby cleaning both sides of the quartz crystal resonator.

Subsequently, a protective mask was formed on the surface of the quartz crystal resonator 1. As shown in FIGS. 3(b) and 3(c), the protective mask 5 was formed on one side of the quartz crystal resonator 1 to cover the surface of the quartz crystal resonator 1 in a state in which only the central region 12a (the sensitive film formation surface) of the electrode 12 is exposed. The protective mask 5 was also formed on the entire other side of the quartz crystal resonator 1 (the electrode and protective mask 5 on the other side are not shown). A thermally peelable resin sheet (product name: Riva Alpha (registered trademark), manufactured by Nitto Denko Corporation) was used as the protective mask 5.

### (Sensitive Film Formation Process)

Next, as shown in FIG. 3(d), the sensitive film 4 was formed on the central region 12a (the sensitive film formation surface) of the electrode 12 of the quartz crystal resonator 1 on which the protective mask 5 was formed, using a raw material solution manufactured by a method to be described below.

### “Manufacturing of Raw Material Solution”

1 g of triethylenediamine, which is a tertiary amine, was added to 10 mL of ion-exchanged water, and dissolved by stirring using a magnetic stirrer to obtain a tertiary amine solution. 0.16 g of dodecylbenzenesulfonic acid (DBSA) (trade name: n-dodecylbenzenesulfonic acid, manufactured by Kanto Chemical Co., Inc.), which is an acid, was added dropwise to the obtained tertiary amine solution and stirred using a magnetic stirrer to obtain a first solution (a first solution preparation process).

Subsequently, 10 g of polystyrene (molecular weight 35,000, trade name: polystyrene, manufactured by Sigma-Aldrich Inc.), which is a polymer, was dissolved in 50 mL of acetone, which is a dispersion solvent, to obtain a second solution (a second solution preparation process).

Subsequently, the second solution was added dropwise to the first solution during stirring using the magnetic stirrer. After the second solution was added dropwise, the stirring using the magnetic stirrer was continued for 1 hour, and ultrasonic dispersion was further performed for 10 minutes. Thereby, a raw material solution in which the first solution and the second solution were dispersed was obtained (a raw material solution preparation process).

Subsequently, the raw material solution produced by the above-described method was applied to the central region 12a (the sensitive film formation surface) of the electrode 12 of the quartz crystal resonator 1 by dropping 15 μL of the raw material solution using a micropipette. Subsequently, the quartz crystal resonator 1 to which the raw material solution was applied was dried at 100° C. for 30 minutes in a nitrogen atmosphere. Thereby, the sensitive film 4 with a thickness of 1.5 μm attached to the sensitive film formation surface on the quartz crystal resonator 1 was obtained, as shown in FIG. 3(d).

Subsequently, the protective mask 5 was removed from the quartz crystal resonator 1 on which the sensitive film 4 was formed. The protective mask 5 was removed by heating the protective mask 5 for 10 minutes at a temperature of 110° C. in a nitrogen atmosphere.

The sensor element of Inventive Example 1 was obtained by the above process.

[Comparative Example 1] The sensor element of Comparative Example 1 was obtained as in Inventive Example 1, except that the first solution prepared in Inventive Example 1 was used instead of the raw material solution.

[Comparative Example 2] A sensor element of Comparative Example 2 was obtained as in Inventive Example 1, except that the second solution prepared in Inventive Example 1 was used instead of the raw material solution.

[Comparative Example 3] A sensor element of Comparative Example 3 was obtained as in Inventive Example 1, except that the tertiary amine solution prepared in Inventive Example 1 was used instead of the raw material solution.

[Comparative Example 4] A sensor element of Comparative Example 4 was obtained as in Inventive Example 1, except that 0.16 g of dodecylbenzenesulfonic acid (DBSA) was used instead of the raw material solution.

[Comparative Example 5] “Production of raw material solution”

0.25 g of polyaniline (product name: polyaniline (emeraldine salt), manufactured by Aldrich), which is a polymer, was added to 10 mL of N-methylpyrrolidone (NMP), which is a dispersion solvent, and dissolved by stirring using a magnetic stirrer. 0.013 g of dodecylbenzenesulfonic acid (DBSA) (product name: n-dodecylbenzenesulfonic acid, manufactured by Kanto Chemical Co., Inc.), which is an acid, was added to the obtained solution as a dopant, and the mixture was stirred for 30 minutes using a magnetic stirrer to obtain a raw material solution for Comparative Example 5.

A sensor element for Comparative Example 5 was obtained as in Inventive Example 1, except that the raw material solution for Comparative Example 5 produced by the above-described method was used instead of the raw material solution for Inventive Example 1.

The materials used for the sensitive film 4 in the sensor elements for Inventive Example 1 and Comparative Examples 1 to 5 are shown in Table 1.

TABLE 1

| | | | | Gas Concentration | Sensitivity Δf (Hz) | | Gas |
|---|---|---|---|---|---|---|---|
| | Tertiary Amine | Acid | Polymer | (ppm) | Formaldehyde | Ethanol | Selectivity |
| Inventive | Triethylenediamine | Dodecylbenzenesulfonic | Polystyrene | 5 | 30 | 0.1 | 300 |
| Example 1 | | Acid | | | | | |
| Comparative | Triethylenediamine | Dodecylbenzenesulfonic | — | 5 | 0 | 0 | 0.0 |
| Example 1 | | Acid | | | | | |
| Comparative | — | — | Polystyrene | 5 | 0 | 0.1 | 0.0 |
| Example 2 | | | | | | | |
| Comparative | Triethylenediamine | — | — | 5 | 0 | 0.01 | 0.0 |
| Example 3 | | | | | | | |
| Comparative | — | Dodecylbenzenesulfonic | — | 5 | 0 | 0.01 | 0.0 |
| Example 4 | | Acid | | | | | |
| Comparative | — | Dodecylbenzenesulfonic | Polyaniline | 5 | 5 | 50 | 0.1 |
| Example 5 | | Acid | | | | | |

[Sensitivity measurement] As the sensor element 10, any one of the sensor elements of Inventive Example 1 and Comparative Examples 1 to 5 manufactured by the above-described method was installed in the flow cell 81. Also, using the gas measuring device 100 shown in FIG. 4 in which a model with the product name THQ-100P-SW (manufactured by TAMADEVICE Co., Ltd.) is installed as the frequency measuring device 82, the frequency variation of the sensor element for formaldehyde gas and ethanol gas was examined by a method to be described below.

An electric field was applied to the electrode 12 of the quartz crystal resonator 1 via the lead wire from the frequency measuring device 82. While a vibration frequency (a frequency) at which the quartz crystal resonator 1 oscillates is continuously measured by the frequency measuring device 82, the gas supply means 83 and the gas exhaust means 84 were operated to supply a base gas consisting of dry air to the flow cell 81 at a flow rate of 500 cc/sec for one hour, and the fundamental frequency (baseline) was stabilized.

Subsequently, a gas was supplied to the flow cell 81 for 5 minutes by the gas supply means 83 at a flow rate of 500 cc/sec and a vibration frequency (a frequency) at that time was measured by the frequency measuring device 82.

Only the base gas was supplied to the flow cell 81 for 1 minute, the base gas and the detection target gas (formaldehyde gas or ethanol gas) were mixed and supplied for 2 minutes so that the gas concentration of the detection target gas was 5 ppm, and then only the base gas was supplied for another 2 minutes.

Subsequently, the base gas was supplied to the flow cell 81 by the gas supply means 83 at a flow rate of 500 cc/sec until the vibration frequency (the frequency) at which the quartz crystal resonator 1 oscillates reached the baseline.

Also, the frequency measuring device 82 detected a difference (a frequency variation) between the average vibration frequency (frequency) and the baseline when the detection target gas (formaldehyde or ethanol gas) was supplied at a gas concentration of 5 ppm, as sensitivity, and output a detection result to the personal computer 85. The detection result is shown in Table 1.

Moreover, a ratio of a variation in the vibration frequency when formaldehyde gas was supplied to a variation in the frequency when ethanol gas was supplied (formaldehyde/ethanol gas) was calculated to evaluate the gas selectivity of the sensor element. Evaluation results are shown in Table 1.

As shown in Table 1, it was confirmed that the sensor element of Inventive Example 1 with a sensitive film containing triethylenediamine, which is a tertiary amine, dodecylbenzenesulfonic acid (DBSA), which is an acid, and polystyrene, which is a polymer, has a large frequency variation (sensitivity) for formaldehyde and is able to detect aldehyde gas.

Moreover, as shown in Table 1, the sensor element of Inventive Example 1 has significantly high gas selectivity. From this, it was confirmed that the sensor element of Inventive Example 1 can selectively detect aldehyde gas in a mixed gas containing the aldehyde gas and ethanol gas.

Moreover, as shown in Table 1, sensor elements of Comparative Example 1 having a sensitive film that does not contain a polymer, Comparative Example 2 having a sensitive film made only of polystyrene, which is a polymer, Comparative Example 3 having a sensitive film made only of a tertiary amine, Comparative Example 4 having a sensitive film made only of an acid, and Comparative Example 5 having a sensitive film made of polyaniline, which is a polymer, and an acid, have a small frequency variation (sensitivity) for formaldehyde and insufficient gas selectivity.

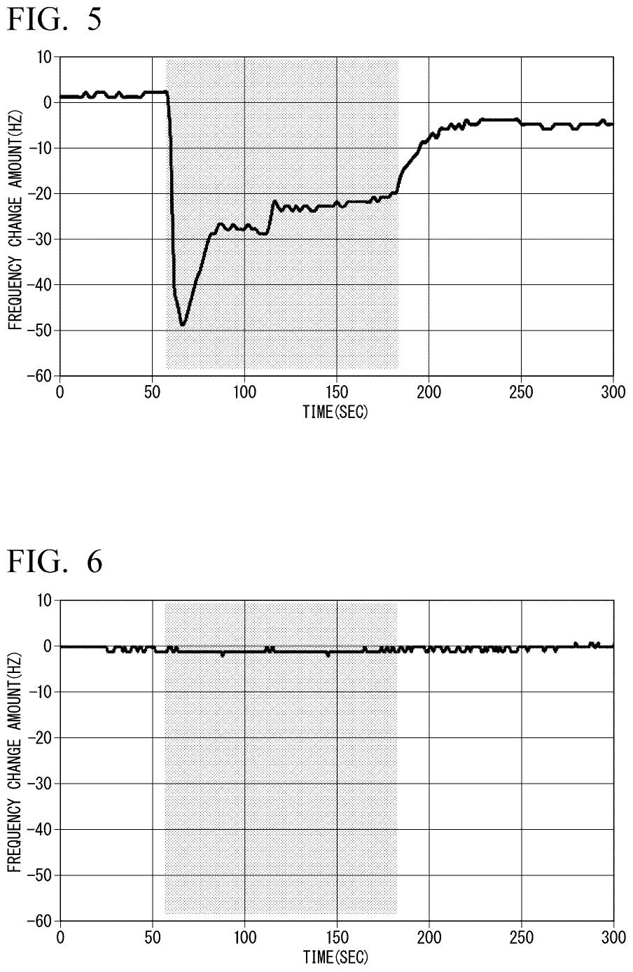

FIG. 5 is a graph showing a vibration frequency variation when formaldehyde gas is supplied to a flow cell in which the sensor element of Inventive Example 1 is installed. FIG. 6 is a graph showing a vibration frequency variation when ethanol gas is supplied to a flow cell in which the sensor element of Inventive Example 1 is installed.

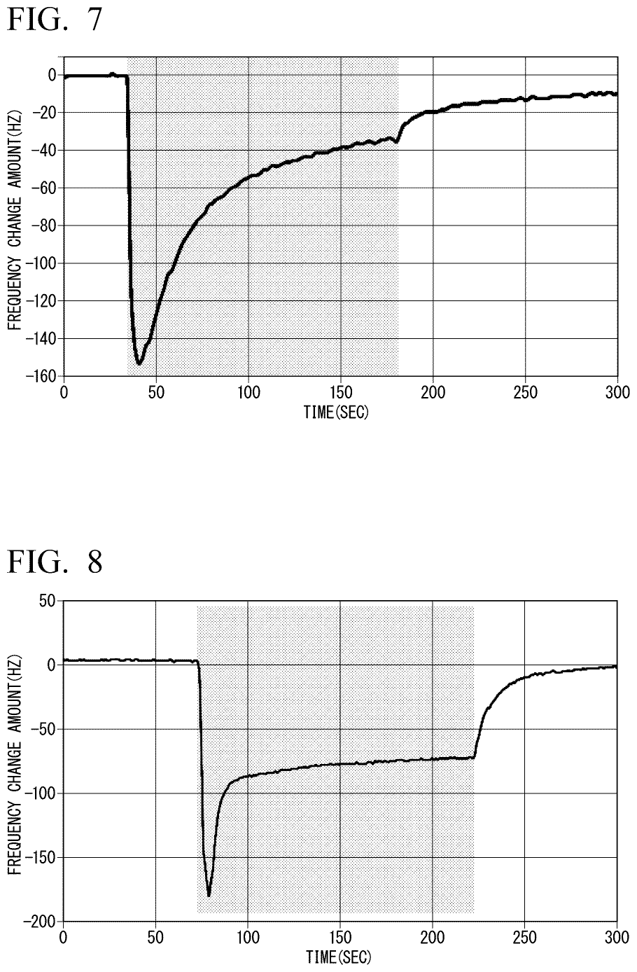

Moreover, FIG. 7 is a graph showing a vibration frequency variation when formaldehyde gas is supplied to a flow cell in which the sensor element of Comparative Example 5 is installed. FIG. 8 is a graph showing a vibration frequency variation when ethanol gas is supplied to a flow cell in which the sensor element of Comparative Example 5 is installed.

As shown in FIGS. 5 and 6, it can be seen that the sensor element of Inventive Example 1 can detect formaldehyde gas with high sensitivity and does not react with ethanol gas. From this, it was confirmed that the sensor element of Inventive Example 1 can selectively detect a concentration of aldehyde gas in a mixed gas containing the aldehyde gas and ethanol gas with high sensitivity.

On the other hand, as shown in FIGS. 7 and 8, the sensor element of Comparative Example 5 reacts with ethanol gas as well as formaldehyde gas. From this, it can be seen that it is difficult for the sensor element of Comparative Example 5 to selectively detect the concentration of aldehyde gas in a mixed gas containing the aldehyde gas and ethanol gas with high sensitivity.

Moreover, the sensitive film of the sensor element of Inventive Example 1 and the sensitive film of the sensor element of Comparative Example 1 were observed using a scanning electron microscope (SEM; product name: SU-8000, manufactured by Hitachi High-Tech Corporation) at a magnification of 30,000 times for Inventive Example 1 and at a magnification of 20,000 times for Comparative Example 1.

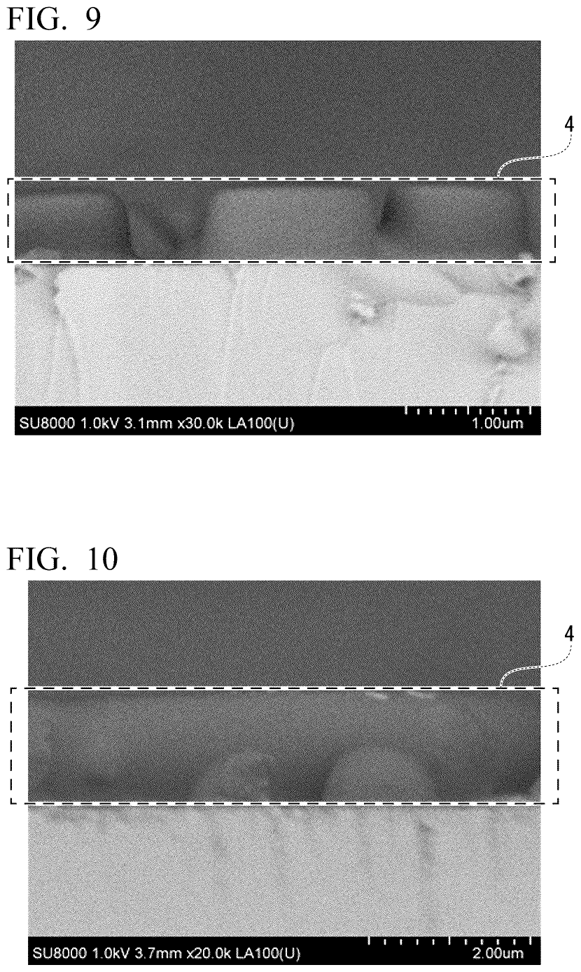

FIG. 9 is a micrograph of the sensitive film of the sensor element of Inventive Example 1. FIG. 10 is a micrograph of the sensitive film of the sensor element of Comparative Example 1.

The average particle size of triethylenediamine, which is a tertiary amine, was measured for the sensitive film of the sensor element of Inventive Example 1 and the sensitive film of the sensor element of Comparative Example 1 by a method to be described below. That is, the surface of the sensitive film was photographed at a magnification of 2,000 times using a scanning electron microscope (SEM; product name: SU-8000, manufactured by Hitachi High-Tech Corporation), and the obtained image was processed using image processing software (product name: Mac-view, manufactured by Mountec Co., Ltd.) to calculate the average particle size.

As a result, the sensitive film 4 of the sensor element of Inventive Example 1 has an average triethylenediamine particle size of 0.8 μm, and contains fine crystals as shown in FIG. 9.

On the other hand, the sensitive film 4 of the sensor element of Comparative Example 1, which does not contain polystyrene, which is a polymer, has an average triethylenediamine particle size of 20 μm, and contains significantly large crystals made of triethylenediamine as compared to the sensitive film 4 of the sensor element of Inventive Example 1 shown in FIG. 9, as shown in FIG. 10.

From this, it was confirmed that the crystal growth of triethylenediamine is suppressed by forming the sensitive film 4 using a method for applying a raw material solution containing triethylenediamine, dodecylbenzenesulfonic acid (DBSA), and polystyrene onto an electrode and drying the raw material solution.

[Second inventive example] Unless otherwise specified, the sensor elements of Inventive Examples A1 to A20 and Comparative Examples A1 to A5 were created by a method similar to that of the first inventive example, and these sensor elements were evaluated by a method similar to that of the first inventive example.

The materials used for the sensitive film 4 in the sensor elements of Inventive Examples A1 to A20 and Comparative Examples A1 to A5 and the evaluation results thereof are shown in Tables 2 and 3.

TABLE 2

| | | | | | | | Gas | | | |
|---|---|---|---|---|---|---|---|---|---|---|
| | Tertiary Amine | | Acid | | Polymer | | Concen- | Sensitivity Δf (Hz) | | Gas |
| | | Parts | | Parts | | Parts | tration | Formal- | | Selec- |
| | Type | by mass | Type | by mass | Type | by mass | (ppm) | dehyde | Ethanol | tivity |
| Inventive | Triethylenediamine | 5 | Dodecylbenzenesulfonic | 1 | Polystyrene | 100 | 5 | 15 | 0.1 | 150 |
| Example A1 | | | Acid | | | | | | | |
| Inventive | Triethylenediamine | 5 | Dodecylbenzenesulfonic | 1.2 | Polystyrene | 100 | 5 | 18 | 0.1 | 180 |
| Example A2 | | | Acid | | | | | | | |
| Inventive | Triethylenediamine | 5 | Dodecylbenzenesulfonic | 1.5 | Polystyrene | 100 | 5 | 20 | 0.1 | 200 |
| Example A3 | | | Acid | | | | | | | |
| Inventive | Triethylenediamine | 5 | Dodecylbenzenesulfonic | 1.8 | Polystyrene | 100 | 5 | 19 | 0.1 | 190 |
| Example A4 | | | Acid | | | | | | | |
| Inventive | Triethylenediamine | 5 | Dodecylbenzenesulfonic | 2.5 | Polystyrene | 100 | 5 | 19 | 0.1 | 190 |
| Example A5 | | | Acid | | | | | | | |
| Inventive | Triethylenediamine | 7 | Dodecylbenzenesulfonic | 1 | Polystyrene | 100 | 5 | 25 | 0.1 | 250 |
| Example A6 | | | Acid | | | | | | | |
| Inventive | Triethylenediamine | 7 | Dodecylbenzenesulfonic | 1.2 | Polystyrene | 100 | 5 | 30 | 0.1 | 300 |
| Example A7 | | | Acid | | | | | | | |
| Inventive | Triethylenediamine | 7 | Dodecylbenzenesulfonic | 1.5 | Polystyrene | 100 | 5 | 28 | 0.1 | 280 |
| Example A8 | | | Acid | | | | | | | |
| Inventive | Triethylenediamine | 7 | Dodecylbenzenesulfonic | 1.8 | Polystyrene | 100 | 5 | 25 | 0.1 | 250 |
| Example A9 | | | Acid | | | | | | | |
| Inventive | Triethylenediamine | 7 | Dodecylbenzenesulfonic | 2.5 | Polystyrene | 100 | 5 | 20 | 0.1 | 200 |
| Example A10 | | | Acid | | | | | | | |
| Inventive | Triethylenediamine | 10 | Dodecylbenzenesulfonic | 1 | Polystyrene | 100 | 5 | 18 | 0.1 | 180 |
| Example A11 | | | Acid | | | | | | | |
| Inventive | Triethylenediamine | 10 | Dodecylbenzenesulfonic | 1.2 | Polystyrene | 100 | 5 | 31 | 0.1 | 310 |
| Example A12 | | | Acid | | | | | | | |

TABLE 3

| | | | | | | | Gas | | | |
|---|---|---|---|---|---|---|---|---|---|---|
| | Tertiary Amine | | Acid | | Polymer | | Concen- | Sensitivity Δf (Hz) | | Gas |
| | | Parts | | Parts | | Parts | tration | Formal- | | Selec- |
| | Type | by mass | Type | by mass | Type | by mass | (ppm) | dehyde | Ethanol | tivity |
| Inventive | Triethylenediamine | 10 | Dodecylbenzenesulfonic | 1.5 | Polystyrene | 100 | 5 | 30 | 0.1 | 300 |
| Example A13 | | | Acid | | | | | | | |
| Inventive | Triethylenediamine | 10 | Dodecylbenzenesulfonic | 1.8 | Polystyrene | 100 | 5 | 27 | 0.1 | 270 |
| Example A14 | | | Acid | | | | | | | |
| Inventive | Triethylenediamine | 10 | Dodecylbenzenesulfonic | 2.5 | Polystyrene | 100 | 5 | 20 | 0.1 | 200 |
| Example A15 | | | Acid | | | | | | | |
| Inventive | Triethylenediamine | 15 | Dodecylbenzenesulfonic | 1 | Polystyrene | 100 | 5 | 14 | 0.1 | 143 |
| Example A16 | | | Acid | | | | | | | |
| Inventive | Triethylenediamine | 15 | Dodecylbenzenesulfonic | 1.2 | Polystyrene | 100 | 5 | 17 | 0.1 | 171 |
| Example A17 | | | Acid | | | | | | | |
| Inventive | Triethylenediamine | 15 | Dodecylbenzenesulfonic | 1.5 | Polystyrene | 100 | 5 | 19 | 0.1 | 190 |
| Example A18 | | | Acid | | | | | | | |
| Inventive | Triethylenediamine | 15 | Dodecylbenzenesulfonic | 1.8 | Polystyrene | 100 | 5 | 18 | 0.1 | 181 |
| Example A19 | | | Acid | | | | | | | |
| Inventive | Triethylenediamine | 15 | Dodecylbenzenesulfonic | 2.5 | Polystyrene | 100 | 5 | 18 | 0.1 | 181 |
| Example A20 | | | Acid | | | | | | | |
| Comparative | Triethylenediamine | 8 | Dodecylbenzenesulfonic | 1.2 | — | — | 5 | 0 | 0.1 | 0 |
| Example A1 | | | Acid | | | | | | | |
| Comparative | — | — | Dodecylbenzenesulfonic | 1.2 | Polystyrene | 100 | 5 | 0 | 0 | 0 |
| Example A2 | | | Acid | | | | | | | |
| Comparative | Trioctylamine | 8 | Dodecylbenzenesulfonic | 1.2 | Polystyrene | 100 | 5 | 0 | 0 | 0 |
| Example A3 | (liquid) | | Acid | | | | | | | |
| | Diamine | | | | | | | | | |
| Comparative | — | — | — | — | Polyaniline | 100 | 5 | 5 | 50 | 0 |
| Example A4 | | | | | | | | | | |
| Comparative | — | — | — | — | PVA | 100 | 5 | 0.01 | 20 | 0 |
| Example A5 | | | | | | | | | | |

As shown in Tables 2 and 3, it was confirmed that the sensor elements of Inventive Examples A1 to A20 having sensitive films with the compositions shown in Tables 2 and 3 have a large frequency variation (sensitivity) for formaldehyde and can detect aldehyde gas.

Moreover, as shown in Tables 2 and 3, the sensor elements of Inventive Examples A1 to A20 have significantly high gas selectivity. From this, it was confirmed that aldehyde gas can be selectively detected in a mixed gas containing the aldehyde gas and ethanol gas by using the sensor elements of Inventive Examples A1 to A20.

Moreover, as shown in Table 3, sensor elements of Comparative Example A1 having a sensitive film that does not contain a polymer, Comparative Example A2 having a sensitive film that does not contain a tertiary amine, Comparative Example A3 in which the tertiary amine is liquid, and Comparative Examples A4 and A5 in which both a tertiary amine and an acid are not contained and the polymer is polyaniline or polyvinyl alcohol (PVA) have a small frequency variation (sensitivity) for formaldehyde and insufficient gas selectivity.

[Third inventive example] Unless otherwise specified, the sensor elements of Inventive Examples B1 to B7 were created by a method similar to that of Inventive Example 1, and these sensor elements were evaluated by a method similar to that of Inventive Example 1.

In the sensor elements of Inventive Examples B1 to B7, the materials used for the sensitive film 4 and the evaluation results thereof are shown in Table 4.

TABLE 4

| | | | | | | | Gas | | | |
|---|---|---|---|---|---|---|---|---|---|---|
| | Tertiary Amine | | Acid | | Polymer | | Concen- | Sensitivity Δf (Hz) | | Gas |
| | | Parts | | Parts | | Parts | tration | Formal- | | Selec- |
| | Type | by mass | Type | by mass | Type | by mass | (ppm) | dehyde | Ethanol | tivity |
| Inventive | Triethylenediamine | 7 | Dodecylbenzenesulfonic | 1.2 | Polystyrene | 100 | 5 | 30 | 0.1 | 300 |
| Example B1 | (Solid) | | Acid | | | | | | | |
| Inventive | Triethylenediamine | 7 | Dodecylbenzenesulfonic | 1.2 | PMMA | 100 | 5 | 30 | 0.1 | 300 |
| Example B2 | (Solid) | | Acid | | | | | | | |
| Inventive | Triethylenediamine | 7 | Dodecylbenzenesulfonic | 1.2 | Polyimide | 100 | 5 | 28 | 0.1 | 280 |
| Example B3 | (Solid) | | Acid | | | | | | | |
| Inventive | Triethylenediamine | 7 | HCl | 1.2 | Polystyrene | 100 | 5 | 27 | 0.3 | 90 |
| Example B4 | (Solid) | | | | | | | | | |
| Inventive | Triethylenediamine | 7 | Acetic Acid | 1.2 | Polystyrene | 100 | 5 | 28 | 0.2 | 140 |
| Example B5 | (Solid) | | | | | | | | | |
| Inventive | Diaminopyridine | 7 | Dodecylbenzenesulfonic | 1.2 | Polystyrene | 100 | 5 | 28 | 0.2 | 140 |
| Example B6 | (Solid) | | Acid | | | | | | | |
| Inventive | Dibenzylethanolamine | 7 | Dodecylbenzenesulfonic | 1.2 | Polystyrene | 100 | 5 | 20 | 0.3 | 67 |
| Example B7 | (Solid) | | Acid | | | | | | | |

As shown in Table 4, it was confirmed that the sensor elements of Inventive Examples B1 to B7 having the sensitive film of the composition shown in Table 4 exhibit a large frequency variation (sensitivity) for formaldehyde and can detect aldehyde gas.

Moreover, as shown in Table 4, the sensor elements of Inventive Examples B1 to B7 have significantly high gas selectivity. From this, it was confirmed that aldehyde gas can be selectively detected in a mixed gas containing the aldehyde gas and ethanol gas by using the sensor elements of Inventive Examples B1 to B7.

### INDUSTRIAL APPLICABILITY

By using the quartz crystal microbalance (QCM) method, aldehyde gas can be continuously detected with high sensitivity.

### REFERENCE SIGNS LIST

1 Quartz crystal resonator
4 Sensitive film
5 Protective mask
10 Sensor element
11 Quartz crystal plate
12 Electrode
12a Central region
12b Connection region
81 Flow cell
82 Frequency measuring device
83 Gas supply means
84 Gas exhaust means
85 Personal computer
100 Gas measuring device

1. A sensor element comprising:
a quartz crystal plate;
an electrode made of a metallic film provided on the quartz crystal plate; and
a sensitive film formed on the electrode,
wherein the sensitive film contains a tertiary amine, an acid, and a polymer.

2. The sensor element according to claim 1, wherein the tertiary amine is one or more of amines selected from aliphatic amines, aromatic amines, and heterocyclic amines, and is solid in a range of 0° C. to 100° C.

3. The sensor element according to claim 1, wherein the acid is one or more of acids selected from inorganic acids, sulfonic acids, and carboxylic acids.

4. The sensor element according to claim 1, wherein the polymer is one or more of polymers selected from polystyrene, polymethyl methacrylate, and polyimide.

5. A gas measuring device comprising the sensor element according to claim 1.

6. A method for manufacturing the sensor element having the sensitive film containing the tertiary amine, the acid, and the polymer according to claim 1, the method comprising:
a step of forming the sensitive film;
a first solution preparation step of preparing a first solution containing the tertiary amine and the acid;
a second solution preparation step of dissolving the polymer in a dispersion solvent to prepare a second solution;
a raw material solution preparation step of mixing the first solution and the second solution to prepare a raw material solution; and
a film formation step of applying and drying the raw material solution.
